(19) United States
(12) Patent Application Publication
(10) Pub. No.: US 2025/0273605 A1
(43) Pub. Date: Aug. 28, 2025

(54) SEMICONDUCTOR DEVICE

(71) Applicant: Mitsubishi Electric Corporation, Tokyo (JP)

(72) Inventor: Satoshi MIYAHARA, Tokyo (JP)

(73) Assignee: Mitsubishi Electric Corporation, Tokyo (JP)

(21) Appl. No.: 18/979,495

(22) Filed: Dec. 12, 2024

(30) Foreign Application Priority Data
Feb. 28, 2024 (JP) 2024-028595

(51) Int. Cl. H01L 23/64; H01L 23/498

(52) U.S. Cl. CPC H01L 23/645; H01L 23/49844

(57) ABSTRACT

An object is to provide a technology that can enhance the magnetic coupling effect. A semiconductor device includes: a P electrode including a first main surface portion and a first external connecting portion; an N electrode including a second main surface portion and a second external connecting portion; and a C electrode including a third main surface portion, and a third-first external connecting portion and a third-second external connecting portion. The first external connecting portion and the third-first external connecting portion are arranged in a direction in which the first main surface portion and the third main surface portion face each other, and the second external connecting portion and the third-second external connecting portion are arranged in a direction in which the second main surface portion and the third main surface portion face each other.

### BACKGROUND OF THE INVENTION

### Field of the Invention

The present disclosure relates to a semiconductor device.

### Description of the Background Art

What has been proposed is connecting, in a semiconductor device including a three-level circuit in one package, a three-level direct potential and a plurality of semiconductor elements with a plurality of electrodes and disposing main surfaces of the plurality of electrodes to face each other (e.g., Japanese Patent Application Laid-Open No. 2014-155287). Under this technology, a current passing through the main surfaces facing each other provides a magnetic coupling effect for reducing the inductance. This can suppress the surge voltage caused by interactions between abrupt current variations in switching the semiconductor elements and the inductance.

However, since the conventional art has not optimized positions of external connectors that are part of the electrodes and are connected to, for example, filter capacitors, there has been room for improvement on the magnetic coupling effect for reducing the inductance.

### SUMMARY

The present disclosure has been made in view of the problem, and has an object of providing a technology that can enhance the magnetic coupling effect.

A semiconductor device includes: a first semiconductor element, a second semiconductor element, a third semiconductor element, and a fourth semiconductor element that are included in a three-level circuit; a P electrode including a first main surface portion and a first external connecting portion connected to a positive electrode of a DC circuit, the P electrode connecting the positive electrode to the first semiconductor element; an N electrode including a second main surface portion and a second external connecting portion connected to a negative electrode of the DC circuit, the N electrode connecting the negative electrode to the second semiconductor element; and a C electrode including a third main surface portion, and a third-first external connecting portion and a third-second external connecting portion that are connected to a neutral point of the DC circuit, the C electrode connecting the neutral point to the third semiconductor element, wherein the first main surface portion and the second main surface portion face and overlap the third main surface portion, the first external connecting portion and the third-first external connecting portion are arranged in a direction in which the first main surface portion and the third main surface portion face each other, and the second external connecting portion and the third-second external connecting portion are arranged in a direction in which the second main surface portion and the third main surface portion face each other.

This can enhance the magnetic coupling effect.

These and other objects, features, aspects, and advantages of the present invention will become more apparent from the following detailed description of the present invention when taken in conjunction with the accompanying drawings.

### BRIEF DESCRIPTION OF THE DRAWINGS

FIG. 1 is a circuit diagram illustrating a three-level circuit including a semiconductor device according to Embodiment 1;

FIG. 2 is a perspective view schematically illustrating a structure of the semiconductor device according to Embodiment 1;

FIG. 3A is a perspective view and FIGS. 3B and 3C are front elevation views all of which schematically illustrate a part of the structure of the semiconductor device according to Embodiment 1;

FIG. 4A is a perspective view and FIGS. 4B to 4D are front elevation views all of which schematically illustrate a part of a structure of a semiconductor device according to Embodiment 2;

FIG. 5A is a perspective view and FIGS. 5B to 5D are front elevation views all of which schematically illustrate a first relevant structure;

FIG. 6A is a perspective view and FIGS. 6B and 6C are front elevation views all of which schematically illustrate a second relevant structure;

FIG. 7A is a perspective view and FIGS. 7B and 7C are front elevation views all of which schematically illustrate a part of a structure of a semiconductor device according to Embodiment 3;

FIG. 8A is a perspective view and FIGS. 8B and 8C are front elevation views all of which schematically illustrate a part of a structure of a semiconductor device according to Embodiment 4; and

FIG. 9A is a perspective view and FIGS. 9B to 9D are front elevation views all of which schematically illustrate a part of a structure of a semiconductor device according to Embodiment 5.

### DESCRIPTION OF THE PREFERRED EMBODIMENTS

Embodiments will be described with reference to the attached drawings. The features to be described in Embodiments below are mere exemplifications, and all of the features are not necessarily essential. In the description below, identical constituent elements in a plurality of Embodiments will be denoted by the same or similar reference numerals, and different constituent elements will be mainly described. In the following description, a particular position and a particular direction such as “up”, “down”, “left”, and “right” need not always coincide with an actual position and an actual direction.

### Embodiment 1

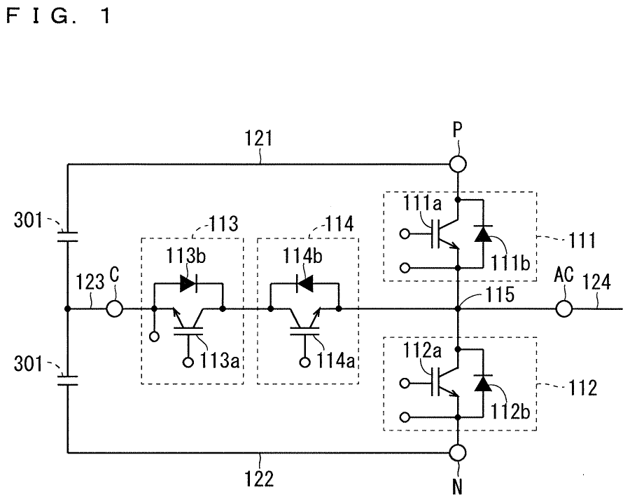

FIG. 1 is a circuit diagram illustrating a three-level circuit including a semiconductor device according to Embodiment 1. The semiconductor device according to Embodiment 1 includes a first semiconductor element 111, a second semiconductor element 112, a third semiconductor element 113, a fourth semiconductor element 114, a P electrode P, an N electrode N, a C electrode C, an AC electrode AC, and an insulating substrate and a package to be described later.

The first semiconductor element 111, the second semiconductor element 112, the third semiconductor element 113, and the fourth semiconductor element 114 include insulated-gate bipolar transistors (IGBTs) 111a, 112a, 113a, and 114a, and freewheeling diodes (FWDs) 111b, 1112b, 113b, and 114b anti-parallel connected to the IGBTs 111a, 112a, 113a, and 114a, respectively.

The first semiconductor element 111 to the fourth semiconductor element 114 may include metal-oxide-semiconductor field-effect transistors (MOSFETs) or reverse conducting IGBTs (RC-IGBTs), instead of the IGBTs 111a, 112a, 113a, and 114a. The FWDs 111b to 114b are, for example, Schottky barrier diodes (SBD) or p-n junction diodes (PND).

The first semiconductor element 111 to the fourth semiconductor element 114 may be made of silicon (Si), or a wide-bandgap semiconductor such as silicon carbide (SIC), gallium nitride (GaN), gallium oxide (Ga₂O₃), or diamond. The first semiconductor element 111 to the fourth semiconductor element 114 which are made of the wide-bandgap semiconductor can perform stable operations at high temperatures and high voltages, and accelerate switching speeds. Each of the first semiconductor element 111 to the fourth semiconductor element 114 may be a single semiconductor chip, or include a plurality of semiconductor chips connected in parallel.

An end of a pair of filter capacitors 301 connected in series corresponds to a positive electrode of a DC circuit, and has a positive potential 121. The other end of the pair of filter capacitors 301 connected in series corresponds to a negative electrode of the DC circuit, and has a negative potential 122. A connecting portion of the filter capacitors 301 corresponds to a neutral point of the DC circuit, and has a neutral-point potential 123. A connecting point 115 that connects the first semiconductor element 111, the second semiconductor element 112, and the fourth semiconductor element 114 has a AC potential 124.

A collector of the IGBT 111a is connected to the positive electrode having the positive potential 121. An emitter of the IGBT 111a is connected to a collector of the IGBT 112a through the connecting point 115. An emitter of the IGBT 112a is connected to the negative electrode having the negative potential 122. As described above, the first semiconductor element 111 and the second semiconductor element 112 are connected in series between the positive electrode having the positive potential 121 and the negative electrode having the negative potential 122.

An emitter of the IGBT 113a is connected to the neutral point having the neutral-point potential 123. A collector of the IGBT 113a is connected to a collector of the IGBT 114a. An emitter of the IGBT 114a is connected to the connecting point 115 of the first semiconductor element 111 and the second semiconductor element 112. As described above, the third semiconductor element 113 and the fourth semiconductor element 114 are connected in series between the neutral point having the neutral-point potential 123 and the connecting point 115.

The third semiconductor element 113 and the fourth semiconductor element 114 appropriately select voltages clamped by the filter capacitors 301, so that the three-level circuit with the aforementioned structure outputs stepping voltages. Although the semiconductor device is described above as a T-shaped three-level circuit in which the first semiconductor element 111 to the fourth semiconductor element 114 are connected in a T shape, the semiconductor device is not limited to this. For example, the semiconductor device may be an I-shaped three-level circuit in which four semiconductor elements (e.g., the first semiconductor element 111 to the fourth semiconductor element 114) are connected in an I shape and another two semiconductor elements (e.g., fifth and sixth semiconductor elements) are connected to a neutral point. In this case, the first semiconductor element 111 to the fourth semiconductor element 114 are connected in series between a positive electrode and a negative electrode. Then, the fifth semiconductor element is connected between the neutral point and a connecting point of the first semiconductor element 111 and the second semiconductor element 112, and the sixth semiconductor element is connected between the neutral point and a connecting point of the third semiconductor element 113 and the fourth semiconductor element 114.

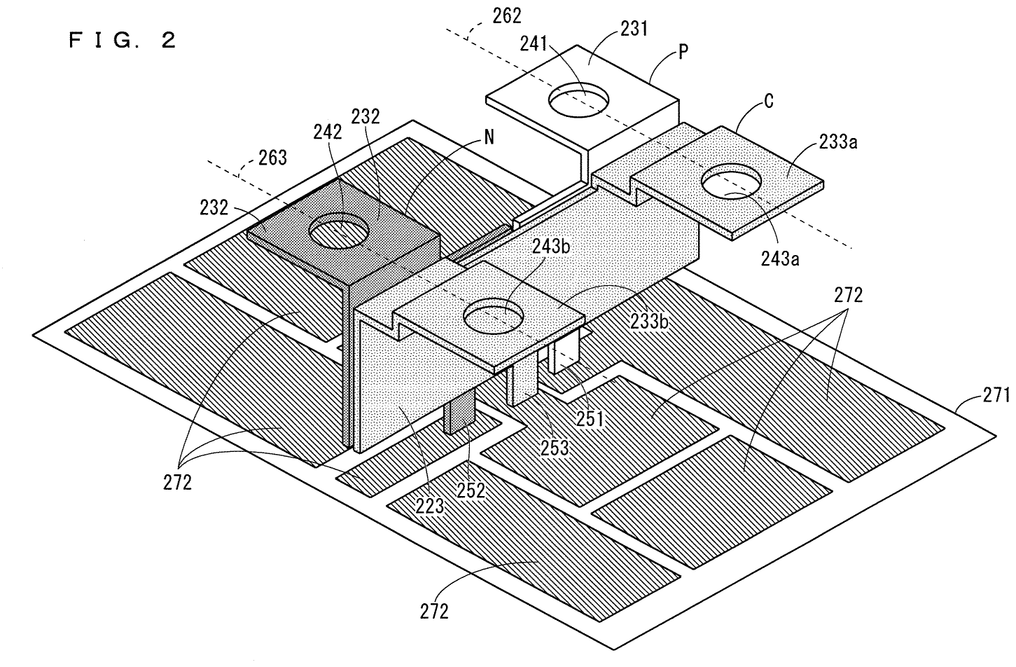

FIG. 2 is a perspective view schematically illustrating a structure of the semiconductor device according to Embodiment 1. Conductive patterns 272 are disposed on an insulating substrate 271, and the first semiconductor element 111 to the fourth semiconductor element 114, which are not illustrated in FIG. 2, are disposed on the conductive patterns 272. The conductive patterns 272 are selectively connected by wires that are not illustrated to complete the circuit in FIG. 1.

Not only the P electrode P, the N electrode N, and the C electrode C but also the AC electrode AC that connects the AC potential 124 not illustrated in FIG. 2 to an external output circuit are disposed on the conductive patterns 272. The structure in FIG. 2 is almost covered with a package that is not illustrated.

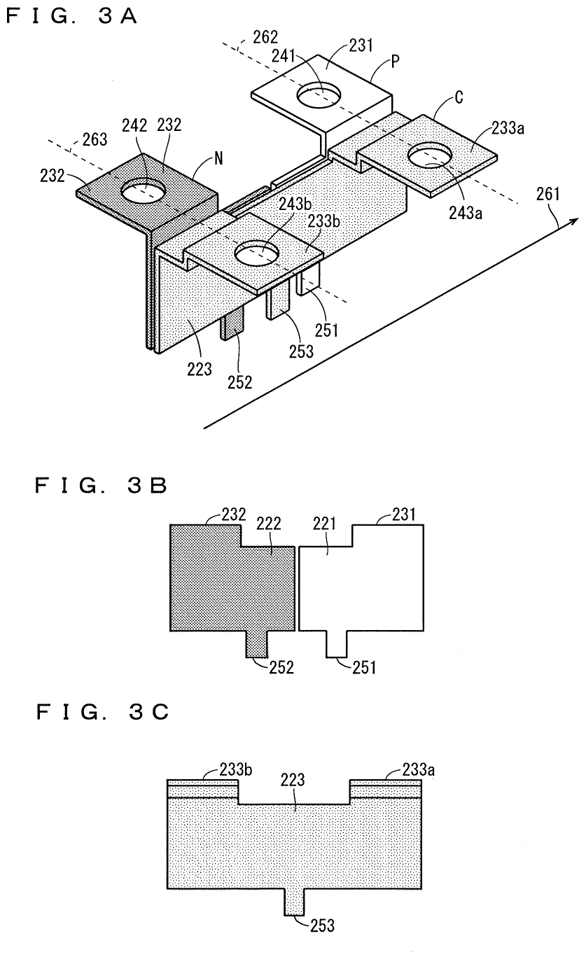

FIG. 3A is a perspective view and FIGS. 3B and 3C are front elevation views all of which schematically illustrate a structure of the P electrode P, the N electrode N, and the C electrode C according to Embodiment 1.

As illustrated in FIGS. 3A and 3B, the P electrode P includes a P main surface portion 221 that is a first main surface portion, a P external connecting portion 231 that is a first external connecting portion, and a P internal connecting portion 251 that is a first internal connecting portion.

The P external connecting portion 231 is formed at an upper portion of the P main surface portion 221, and is connected to the positive electrode having the positive potential 121 in FIG. 1 through an external wire such as a bus bar. The P external connecting portion 231 is provided with an attachment hole 241 for connecting the external wire via a screw. The P internal connecting portion 251 is formed at a lower portion of the P main surface portion 221, and is connected to the first semiconductor element 111 in FIG. 1 through the conductive pattern 272 in FIG. 2. Although the number of each of the P external connecting portions 231 and the P internal connecting portions 251 is one in Embodiment 1, the number may be multiple.

As illustrated in FIGS. 3A and 3B, the N electrode N includes an N main surface portion 222 that is a second main surface portion, an N external connecting portion 232 that is a second external connecting portion, and an N internal connecting portion 252 that is a second internal connecting portion.

The N external connecting portion 232 is formed at an upper portion of the N main surface portion 222, and is connected to the negative electrode having the negative potential 122 in FIG. 1 through an external wire such as a bus bar. The N external connecting portion 232 is provided with an attachment hole 242 for connecting the external wire via a screw. The N internal connecting portion 252 is formed at a lower portion of the N main surface portion 222, and is connected to the second semiconductor element 112 in FIG. 1 through the conductive pattern 272 in FIG. 2. Although the number of each of the N external connecting portions 232 and the N internal connecting portions 252 is one in Embodiment 1, the number may be multiple.

As illustrated in FIGS. 3A and 3C, the C electrode C includes a C main surface portion 223 that is a third main surface portion, a first C external connecting portion 233a that is a third-first external connecting portion, a second C external connecting portion 233b that is a third-second external connecting portion, and a C internal connecting portion 253 that is a third internal connecting portion.

The first C external connecting portion 233a and the second C external connecting portion 233b are formed at upper portions of the C main surface portion 223, and are connected to the neutral point having the neutral-point potential 123 in FIG. 1 through external wires such as bus bars. The first C external connecting portion 233a and the second C external connecting portion 233b are provided with an attachment hole 243a and an attachment hole 243b, respectively, for connecting the external wires via screws. The C internal connecting portion 253 is formed at a lower portion of the C main surface portion 223, and is connected to the third semiconductor element 113 in FIG. 1 through the conductive pattern 272 in FIG. 2.

Although the number of each of the first C external connecting portions 233a and the second C external connecting portions 233b is one in Embodiment 1, the number is not limited to this. The number of the first C external connecting portions 233a should be identical to that of the P external connecting portions 231, and the number of the second C external connecting portions 233b should be identical to that of the N external connecting portions 232. Although the number of the C internal connecting portions 253 is one in Embodiment 1, the number may be multiple as will be described later in Embodiment 3.

As illustrated in FIG. 3A, the P main surface portion 221 and the N main surface portion 222 face and overlap the C main surface portion 223. In Embodiment 1, the P main surface portion 221 and the N main surface portion 222 face one surface of the C main surface portion 223, and the P main surface portion 221 and the N main surface portion 222 are in close proximity to each other. Each of the P main surface portion 221 to the C main surface portion 223 may be almost planar, and partly bent to facilitate connection to the conductive patterns 272 and the bus bars.

The P external connecting portions 231 and the first C external connecting portions 233a are arranged in a direction 262 in which the P main surface portion 221 and the C main surface portion 223 face each other. The positions of the P external connecting portions 231 and the first C external connecting portions 233a are identical in a horizontal axis 261. The positions of the attachment hole 241 and the attachment hole 243a are identical in the horizontal axis 261.

The N external connecting portion 232 and the second C external connecting portion 233b are arranged in a direction 263 in which the N main surface portion 222 and the C main surface portion 223 face each other. The positions of the N external connecting portion 232 and the second C external connecting portion 233b are identical in the horizontal axis 261. The positions of the attachment hole 242 and the attachment hole 243b are identical in the horizontal axis 261.

In Embodiment 1, the P external connecting portion 231 and the N external connecting portion 232 are aligned in a row along the horizontal axis 261, and the first C external connecting portion 233a and the second C external connecting portion 233b are aligned in another row along the horizontal axis 261.

When the semiconductor device includes multiple pairs of the P external connecting portion 231 and the first C external connecting portion 233a, the P external connecting portion 231 and the first C external connecting portion 233a in each of the pairs are preferably arranged in the direction 262. Similarly, when the semiconductor device includes multiple pairs of the N external connecting portion 232 and the second C external connecting portion 233b, the N external connecting portion 232 and the second C external connecting portion 233b in each of the pairs are preferably arranged in the direction 263. The P external connecting portion 231 and the N external connecting portion 232 may be or need not be in close proximity to each other.

### Summary of Embodiment 1

In Embodiment 1, the P main surface portion 221 and the N main surface portion 222 face and overlap the C main surface portion 223. Since the magnetic coupling effect in such a structure can reduce the inductance each between the positive electrode and the neutral point and between the neutral point and the negative electrode, the surge voltage occurring in switching the semiconductor elements can be reduced.

In Embodiment 1, the P external connecting portions 231 and the first C external connecting portions 233a are arranged in the direction 262. The N external connecting portion 232 and the second C external connecting portion 233b are arranged in the direction 263. Since inlets and outlets of current paths of the P electrode and the C electrode C overlap each other and inlets and outlets of current paths of the C electrode C and the N electrode N overlap each other in such a structure, the magnetic coupling effect can be enhanced, and the inductance and the surge voltage can be further reduced. Similarly, since overlapping of inlets and outlets of current paths of the bus bars can be expected, additional enhancement of the magnetic coupling effect can also be expected.

In Embodiment 1, the P external connecting portion 231 and the N external connecting portion 232 are aligned in a row, and the first C external connecting portion 233a and the second C external connecting portion 233b are aligned in another row. Such a structure can shape the bus bar to be connected to the first C external connecting portion 233a and the second C external connecting portion 233b into a simple plate. This can consequently simplify manufacturing of external wires and reduce the cost.

### Embodiment 2

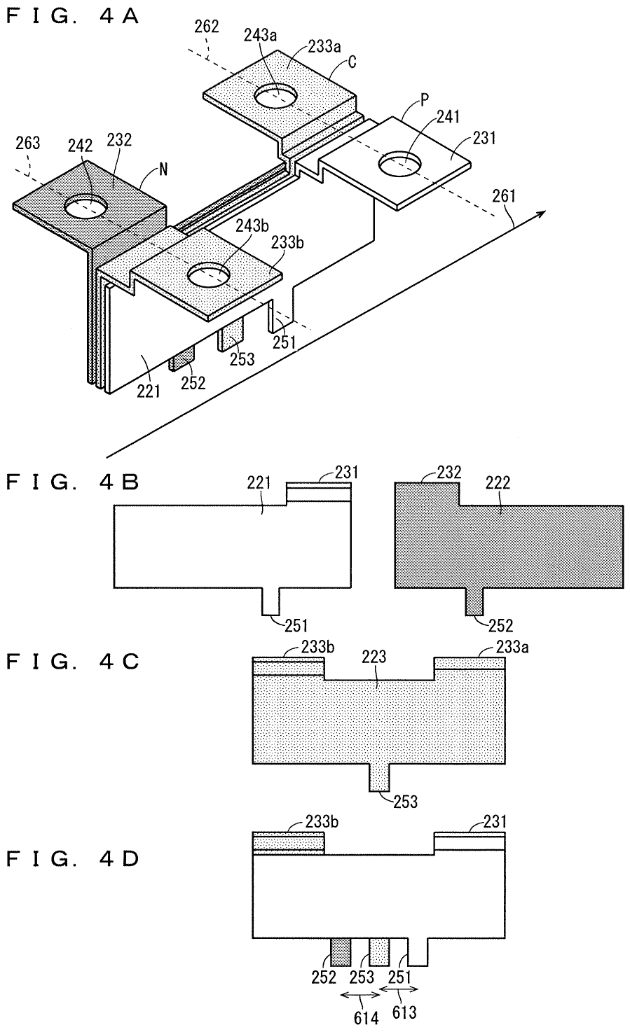

FIG. 4A is a perspective view and FIGS. 4B to 4D are front elevation views all of which schematically illustrate a structure of the P electrode P, the N electrode N, and the C electrode C according to Embodiment 2.

In Embodiment 2, the P external connecting portion 231 and the second C external connecting portion 233b are aligned in a row along the horizontal axis 261, and the N external connecting portion 232 and the first C external connecting portion 233a are aligned in another row along the horizontal axis 261.

Consequently, the P main surface portion 221 can face the first surface of the C main surface portion 223, and the N main surface portion 222 can face the second surface on the other side of the first surface of the C main surface portion 223. In other words, a region of the P main surface portion 221 which overlaps the C main surface portion 223 and a region of the N main surface portion 222 which overlaps the C main surface portion 223 can be increased. This can enhance the magnetic coupling effect, and further reduce the inductance in each of the current path of the P electrode P and the C electrode C and the current path of the C electrode C and the N electrode N. Thus, the surge voltage can be further reduced.

As illustrated in the front elevation views of the P electrode P, the N electrode N, and the C electrode C, the C internal connecting portion 253 is closer to the center of each of the main surface portions than the P internal connecting portion 251 and the N internal connecting portion 252 in Embodiment 2.

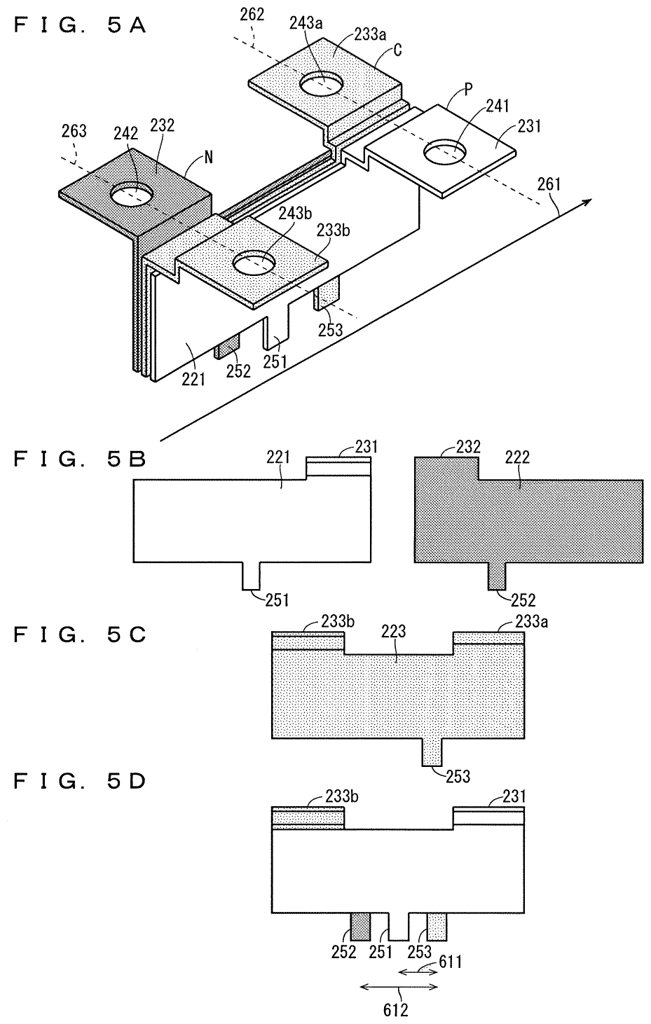

FIG. 5A is a perspective view and FIGS. 5B to 5D are front elevation views all of which schematically illustrate a structure (hereinafter referred to as a “first relevant structure”) which is relevant to the structure of the P electrode P, the N electrode N, and the C electrode C according to Embodiment 2. In the first relevant structure, the P internal connecting portion 251 or the N internal connecting portion 252 is closer to the center of each of the main surface portions than the C internal connecting portion 253 as illustrated in the front elevation view of the P electrode P, the N electrode N, and the C electrode C of FIG. 5D.

In the structure of FIGS. 5A to 5D, a distance 611 between the P internal connecting portion 251 and the C internal connecting portion 253 becomes smaller than a distance 612 between the C internal connecting portion 253 and the N internal connecting portion 252. Thus, a difference between the magnetic coupling effect between the P electrode P and the C electrode C and the magnetic coupling effect between the C electrode C and the N electrode N becomes large. This results in an increase in a difference between the inductance of the current path of the P electrode P and the C electrode C and the inductance of the current path of the C electrode C and the N electrode N. Thus, a difference between the surge voltages occurring in different operation modes is increased.

In contrast, the C internal connecting portion 253 is closer to the center of each of the main surface portions than the P internal connecting portion 251 and the N internal connecting portion 252 in a front view in Embodiment 2, as illustrated in the front elevation view of the P electrode P, the N electrode N, and the C electrode C in FIG. 4D. Such a structure can reduce a difference between a distance 613 between the P internal connecting portion 251 and the C internal connecting portion 253 and a distance 614 between the C internal connecting portion 253 and the N internal connecting portion 252. Since this can reduce the difference between the surge voltages occurring in the different operation modes, optimization of driving conditions for each of the operation modes becomes unnecessary or is facilitated.

### Embodiment 3

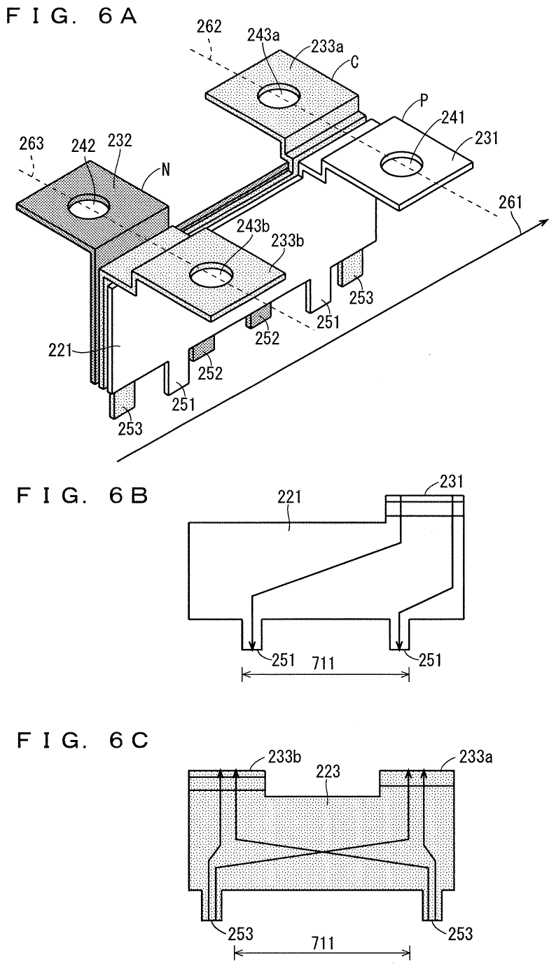

FIG. 6A is a perspective view and FIGS. 6B and 6C are front elevation views all of which schematically illustrate a structure (hereinafter referred to as a “second relevant structure”) which is relevant to the structure of the P electrode P, the N electrode N, and the C electrode C according to Embodiment 3. In the second relevant structure, one of a plurality of P internal connecting portions 251 or a plurality of N internal connecting portions 252 is closer to the center of each of the main surface portions than a plurality of C internal connecting portions 253 in a front view.

In such a structure, current paths of currents which flow from the C internal connecting portions 253 pass outside a current region 711 of a current flowing through the P electrode P as indicated by arrows in FIGS. 6B and 6C. Since a region in which the current region 711 flowing through the P electrode P overlaps the current region 711 flowing through the C electrode C is small, the effect of reducing the inductance by the magnetic coupling becomes smaller.

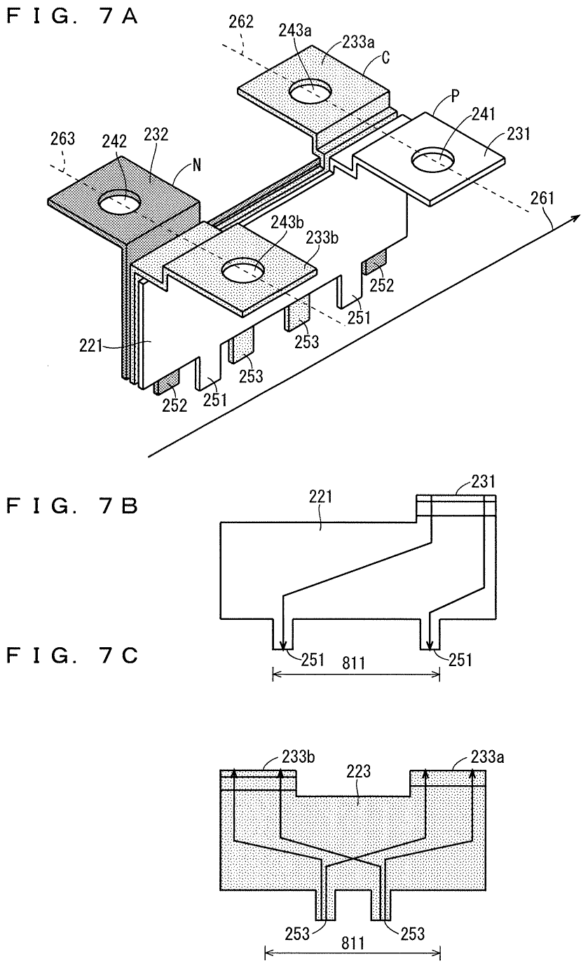

FIG. 7A is a perspective view and FIGS. 7B and 7C are front elevation views all of which schematically illustrate a structure of the P electrode P, the N electrode N, and the C electrode C according to Embodiment 3. In Embodiment 3, the plurality of C internal connecting portions 253 are closer to the center of each of the main surface portions than the plurality of P internal connecting portions 251 and the plurality of N internal connecting portions 252 in a front view. Since a region in which a current region 811 flowing through the P electrode P overlaps the current region 811 flowing through the C electrode C is large in such a structure, the effect of reducing the inductance by the magnetic coupling between the P electrode P and the C electrode C can be enhanced. Thus, the surge voltage can be reduced. This holds true for the magnetic coupling between the C electrode C and the N electrode N.

### Embodiment 4

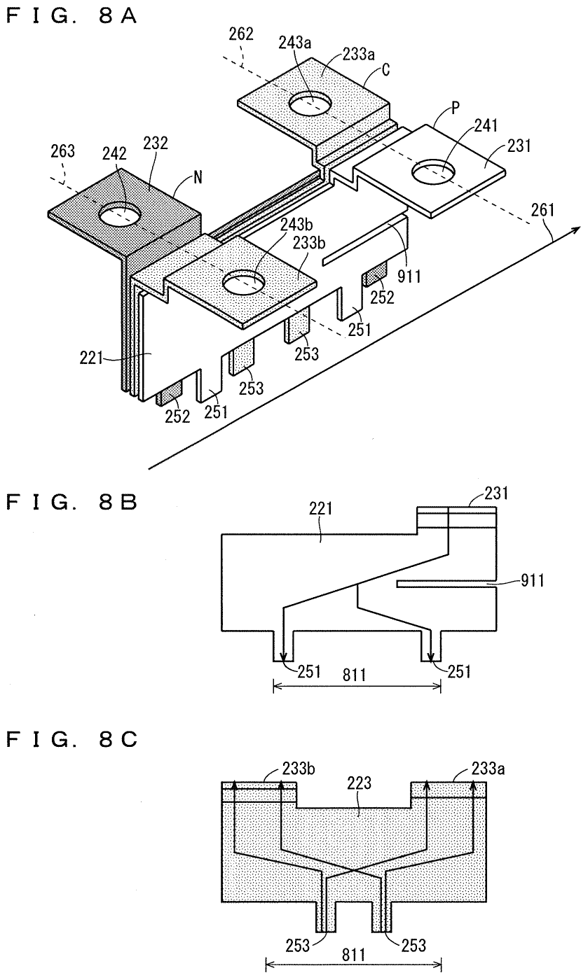

FIG. 8A is a perspective view and FIGS. 8B and 8C are front elevation views all of which schematically illustrate a structure of the P electrode P, the N electrode N, and the C electrode C according to Embodiment 4. In Embodiment 4, a slit 911 extends in a horizontal direction and is provided in the P main surface portion 221. One or more of the slits 911 should extend in the horizontal direction and be provided in at least one of the P main surface portion 221, the N main surface portion 222, or the C main surface portion 223. In this Description, for example, at least one of A, B, C, . . . , or Z means any one of all combinations obtained by combining one type or more extracted from each of groups of A, B, C, . . . , and Z.

In such a structure, the slit 911 changes current paths of currents such that the current paths pass through the vicinity of the center of the electrode with the slit 911 as indicated by arrows in FIGS. 8B and 8C. This can, for example, increase a region in which a current region of a current flowing through the P electrode P overlaps a current region of a current flowing through the C electrode C, or increase an amount of a current passing through the overlapping region. Since the effect of reducing the inductance by the magnetic coupling between the P electrode P and the C electrode C can be enhanced, the surge voltage can be reduced. This holds true for the magnetic coupling between the C electrode C and the N electrode N.

### Embodiment 5

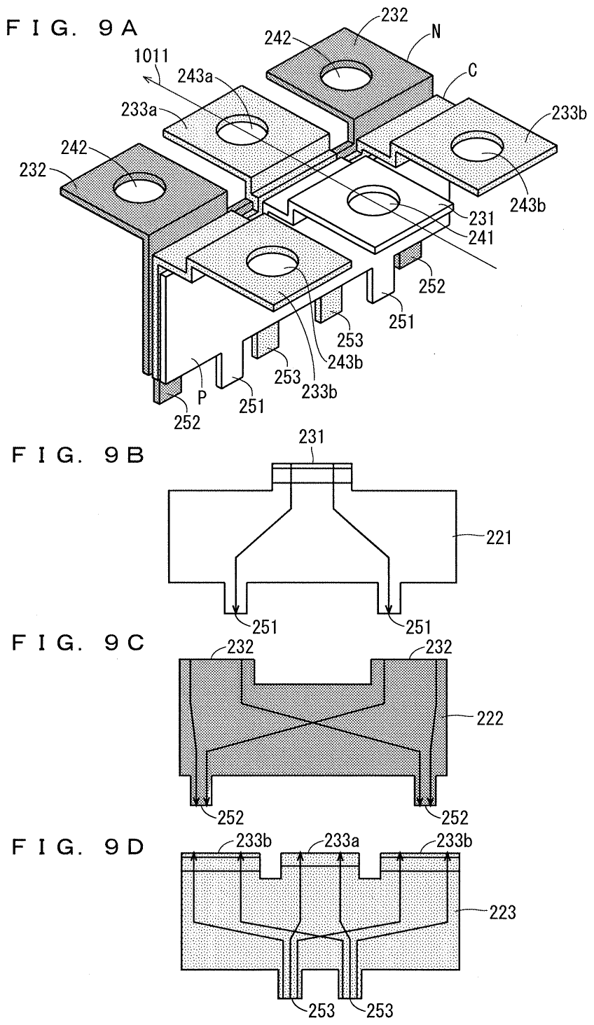

FIG. 9A is a perspective view and FIGS. 9B to 9D are front elevation views all of which schematically illustrate a structure of the P electrode P, the N electrode N, and the C electrode C according to Embodiment 5. In Embodiment 5, one or more of the P external connecting portions 231 (one in FIGS. 9A and 9B) are, for example, line-symmetric about a vertical axis 1011 on a plane of the electrode as a target axis as a whole. In other words, one or more of the P external connecting portions 231 (one in FIGS. 9A and 9B) are line-symmetric or substantially line-symmetric about the vertical axis 1011 as a target axis as a whole.

Similarly, one or more of the N external connecting portions 232 (two in FIGS. 9A and 9C), one or more of the first C external connecting portions 233a (one in FIGS. 9A and 9D), and one or more of the second C external connecting portions 233b (two in FIGS. 9A and 9D) are line-symmetric as a whole.

Such a structure can reduce deviations of current paths of currents flowing through the P electrode P and the N electrode N. Since the effect of reducing the inductance by the magnetic coupling with the C electrode C can be enhanced, the surge voltage can be reduced. Since the difference in inductance between the current paths can be reduced, the current balance between a plurality of chips can be enhanced, and a deviation in chip temperature caused by the current balance can be reduced.

Embodiments and the modifications can be freely combined, and appropriately modified or omitted.

A summary of various aspects of the present disclosure will be hereinafter described as Appendixes.

### Appendix 1

A semiconductor device, comprising:
a first semiconductor element, a second semiconductor element, a third semiconductor element, and a fourth semiconductor element that are included in a three-level circuit;
a P electrode including a first main surface portion and a first external connecting portion connected to a positive electrode of a DC circuit, the P electrode connecting the positive electrode to the first semiconductor element;
an N electrode including a second main surface portion and a second external connecting portion connected to a negative electrode of the DC circuit, the N electrode connecting the negative electrode to the second semiconductor element; and
a C electrode including a third main surface portion, and a third-first external connecting portion and a third-second external connecting portion that are connected to a neutral point of the DC circuit, the C electrode connecting the neutral point to the third semiconductor element,
wherein the first main surface portion and the second main surface portion face and overlap the third main surface portion,
the first external connecting portion and the third-first external connecting portion are arranged in a direction in which the first main surface portion and the third main surface portion face each other, and
the second external connecting portion and the third-second external connecting portion are arranged in a direction in which the second main surface portion and the third main surface portion face each other.

### Appendix 2

The semiconductor device according to appendix 1,
wherein the first semiconductor element and the second semiconductor element are connected in series between the positive electrode and the negative electrode, and
the third semiconductor element and the fourth semiconductor element are connected in series between the neutral point and a connecting point of the first semiconductor element and the second semiconductor element.

### Appendix 3

The semiconductor device according to appendix 1, further comprising
a fifth semiconductor element and a sixth semiconductor element that are included in the three-level circuit,
wherein the first semiconductor element, the second semiconductor element, the third semiconductor element, and the fourth semiconductor element are connected in series between the positive electrode and the negative electrode,
the fifth semiconductor element is connected between the neutral point and a connecting point of the first semiconductor element and the second semiconductor element, and
the sixth semiconductor element is connected between the neutral point and a connecting point of the third semiconductor element and the fourth semiconductor element.

### Appendix 4

The semiconductor device according to any one of appendixes 1 to 3,
wherein the first external connecting portion and the second external connecting portion are aligned in a row, and
the third-first external connecting portion and the third-second external connecting portion are aligned in an other row.

### Appendix 5

The semiconductor device according to any one of appendixes 1 to 3,
wherein the first external connecting portion and the third-second external connecting portion are aligned in a row, and
the second external connecting portion and the third-first external connecting portion are aligned in an other row.

### Appendix 6

The semiconductor device according to any one of appendixes 1 to 5,
wherein the P electrode, the N electrode, and the C electrode further include a first internal connecting portion, a second internal connecting portion, and a third internal connecting portion to be connected to the first semiconductor element, the second semiconductor element, and the third semiconductor element, respectively, and
the third internal connecting portion is closer to a center than the first internal connecting portion and the second internal connecting portion in a front view.

### Appendix 7

The semiconductor device according to appendix 6,
wherein a plurality of the third internal connecting portions are closer to a center than a plurality of the first internal connecting portions and a plurality of the second internal connecting portions in a front view.

### Appendix 8

The semiconductor device according to any one of appendixes 1 to 7,
wherein a slit extends in a horizontal direction and is provided in at least one of the first main surface portion, the second main surface portion, or the third main surface portion.

### Appendix 9

The semiconductor device according to any one of appendixes 1 to 8,
wherein one or more of the first external connecting portions are line-symmetric as a whole, one or more of the second external connecting portions are line-symmetric as a whole, and one or more of the third-first external connecting portions and one or more of the third-second external connecting portions are line-symmetric as a whole.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device, comprising:
a first semiconductor element, a second semiconductor element, a third semiconductor element, and a fourth semiconductor element that are included in a three-level circuit;
a P electrode including a first main surface portion and a first external connecting portion connected to a positive electrode of a DC circuit, the P electrode connecting the positive electrode to the first semiconductor element;
an N electrode including a second main surface portion and a second external connecting portion connected to a negative electrode of the DC circuit, the N electrode connecting the negative electrode to the second semiconductor element; and
a C electrode including a third main surface portion, and a third-first external connecting portion and a third-second external connecting portion that are connected to a neutral point of the DC circuit, the C electrode connecting the neutral point to the third semiconductor element,
wherein the first main surface portion and the second main surface portion face and overlap the third main surface portion,
the first external connecting portion and the third-first external connecting portion are arranged in a direction in which the first main surface portion and the third main surface portion face each other, and
the second external connecting portion and the third-second external connecting portion are arranged in a direction in which the second main surface portion and the third main surface portion face each other.

2. The semiconductor device according to claim 1,
wherein the first semiconductor element and the second semiconductor element are connected in series between the positive electrode and the negative electrode, and
the third semiconductor element and the fourth semiconductor element are connected in series between the neutral point and a connecting point of the first semiconductor element and the second semiconductor element.

3. The semiconductor device according to claim 1, further comprising
a fifth semiconductor element and a sixth semiconductor element that are included in the three-level circuit,
wherein the first semiconductor element, the second semiconductor element, the third semiconductor element, and the fourth semiconductor element are connected in series between the positive electrode and the negative electrode,
the fifth semiconductor element is connected between the neutral point and a connecting point of the first semiconductor element and the second semiconductor element, and
the sixth semiconductor element is connected between the neutral point and a connecting point of the third semiconductor element and the fourth semiconductor element.

4. The semiconductor device according to claim 1,
wherein the first external connecting portion and the second external connecting portion are aligned in a row, and
the third-first external connecting portion and the third-second external connecting portion are aligned in an other row.

5. The semiconductor device according to claim 1,
wherein the first external connecting portion and the third-second external connecting portion are aligned in a row, and
the second external connecting portion and the third-first external connecting portion are aligned in an other row.

6. The semiconductor device according to claim 1,
wherein the P electrode, the N electrode, and the C electrode further include a first internal connecting portion, a second internal connecting portion, and a third internal connecting portion to be connected to the first semiconductor element, the second semiconductor element, and the third semiconductor element, respectively, and
the third internal connecting portion is closer to a center than the first internal connecting portion and the second internal connecting portion in a front view.

7. The semiconductor device according to claim 6,
wherein a plurality of the third internal connecting portions are closer to a center than a plurality of the first internal connecting portions and a plurality of the second internal connecting portions in a front view.

8. The semiconductor device according to claim 1,
wherein a slit extends in a horizontal direction and is provided in at least one of the first main surface portion, the second main surface portion, or the third main surface portion.

9. The semiconductor device according to claim 1,
wherein one or more of the first external connecting portions are line-symmetric as a whole, one or more of the second external connecting portions are line-symmetric as a whole, and one or more of the third-first external connecting portions and one or more of the third-second external connecting portions are line-symmetric as a whole.
